(19) United States
(12) Patent Application Publication
(10) Pub. No.: US 2021/0397302 A1
(43) Pub. Date: Dec. 23, 2021

(54) TOUCH DISPLAY DEVICE AND FABRICATION METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventors: Jiayao YANG, Wuhan, Hubei (CN); Qipei ZHANG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 16/978,696

(22) PCT Filed: Jul. 21, 2020
(86) PCT No.: PCT/CN2020/103207

§ 371 Date: Sep. 6, 2020

(30) Foreign Application Priority Data
Jun. 22, 2020 (CN) 202010574243.1

(51) Int. Cl. G06F 3/044; G06F 3/041

(52) U.S. Cl. CPC G06F 3/0445; G06F 3/0443; G06F 3/0412; H01L 27/323; G06F 2203/04103; G06F 2203/04111; G06F 3/0446

(57) ABSTRACT

The present application provides a touch display panel having a display module, a touch module, and a plurality of pads located in a peripheral area. The pads include a first pad pattern and a second pad pattern located above the first pad pattern, the second pad pattern covers a top surface of the first pad pattern and exposes sidewalls of the first pad pattern, and the first pad pattern and the second pad pattern are formed in a same etching step.

### FIELD OF INVENTION

The present application relates to a field of touch display technology, and more particularly to a touch display device and a fabrication method thereof.

### BACKGROUND

In a known organic light-emitting diode on-cell touch display (OLED on-cell touch) technology, also known as direct on-cell touch (DOT) technology, integration of display and touch control is realized by directly forming a touch control structure using low-temperature process (with a temperature less than or equal to 90° C.) over a thin-film encapsulation (TFE) in an OLED panel. In a pad structure of a touch display device, a first pad layer 1 is formed by a material of source/drain metal layers. In order to achieve a better bonding effect, a top surface and sidewalls of the first pad layer 1 are exposed. As shown in FIG. 1, the source/drain metal layers will be over etched when an etching is performed to an anode layer of the organic light emitting diode display panel so that a cavity la appears on the sidewall of the first pad layer 1. When a material of the anode layer is ITO/Ag/ITO, it will also cause precipitation of the Ag. A gap exists between a second pad layer 2 and the first pad layer 1 when the second pad layer 2 is subsequently formed on the first pad layer 1, and electrochemical corrosion easily appears in this position after long term operation of the panel, thereby leading to failure of the panel.

### Technical Problem

In view of this, the purpose of the present application is to provide a touch display device and a fabrication method thereof, which can improve the side etching problem of the pad, thereby improving reliability of the panel.

### Technical Solution

An embodiment of the present application provides a touch display panel having a stacked display module and a touch module, comprising: a plurality of pads located in a peripheral area, the pads comprises a first pad pattern and a second pad pattern located above the first pad pattern that is electrically connected to the first pad pattern, the second pad pattern covers a top surface of the first pad pattern and exposes sidewalls of the first pad pattern, the first pad pattern and the second pad pattern are formed in a same etching step, the first pad pattern and source/drain electrodes of the display module are in the same layer, and the second pad pattern and a touch pattern of the touch module are in the same layer.

In one embodiment, the touch module comprises a first touch pattern layer and a second touch pattern layer, the first touch pattern layer is disposed between the second touch pattern layers and the display module, and the second pad pattern and the second touch pattern layer are in the same layer.

In one embodiment, the touch module of the touch display device is a single-layered bridge touch structure, and the second pad pattern and a touch driving electrode and a touch sensing electrode of the touch module are in the same layer.

In one embodiment, the first pad pattern and the second pad pattern are made of the same material.

In one embodiment, the pad further comprises a third pad pattern electrically connected to the second pad pattern, and the second pad pattern is located between the first pad pattern and the third pad pattern, and the third pad pattern and the first pad pattern are in the same layer.

In one embodiment, the sidewalls of the bonding pad are covered by an organic protective layer.

In one embodiment, the touch display device further comprises an inorganic layer disposed between two adjacent pads.

In one embodiment, the touch display device further comprises an inorganic layer and an organic protective layer disposed between two adjacent pads, and the organic protective layer covers the sidewalls of the pads and the inorganic layer.

The present application provides a fabrication method of a touch display device, wherein the touch display device comprises a stacked display module and a touch module, the touch display device comprises a plurality of pads located in a peripheral area, the fabrication method comprising following steps:

providing a substrate, forming a source/drain metal layer on the substrate, and patterning the source/drain metal layer to form a first pre-pad pattern and a source/drain;

forming an anode metal layer on the patterned source/drain metal layer, patterning the anode metal layer, and forming an anode and removing the anode metal layer above the first pre-pad pattern;

forming a touch material layer above the first pre-pad pattern, patterning the touch material layer to form a second pad pattern and a touch pattern, wherein the second pad pattern is located on the first pre-pad pattern and exposes sidewalls of the first pre-pad pattern; and

etching the first pre-pad pattern to form a first pad pattern, wherein the first pad pattern and the second pad pattern are electrically connected to form a solder pad.

In one embodiment, in the step of forming a touch material layer above the first pre-pad pattern, patterning the touch material layer to form a second pad pattern and a touch pattern, an over etching is simultaneously performed to the first pre-pad pattern to form the first pad pattern.

In one embodiment, the touch module comprises a first touch pattern layer and a second touch pattern layer, and the first touch pattern layer is disposed between the second touch pattern layer and the display module, the second pad pattern and the second touch pattern layer are in the same layer.

In one embodiment, the touch module of the touch display device is a single-layer bridge touch structure, and the second pad pattern and a touch driving electrode and a touch sensing electrode of the touch module are in the same layer.

In one embodiment, the first pad pattern and the second pad pattern are made of the same material.

In one embodiment, in the step of forming a touch material layer above the first pre-pad pattern, patterning the touch material layer to form a second pad pattern and a touch pattern, two layers of touch material are sequentially formed above the first pre-pad pattern, and the two layers of touch material are patterned to respectively form stacked second and third pad patterns.

In one embodiment, the fabrication method of the touch display device further comprises forming an organic protective layer covering the sidewalls of the pad.

In one embodiment, the step of forming a touch material layer above the first pre-pad pattern, patterning the touch material layer to form a second pad pattern and a touch pattern further comprises forming an inorganic material layer on the substrate, patterning the inorganic material layer, and removing the inorganic material layer above and around the first pre-pad pattern to form an inorganic layer.

In one embodiment, the step of forming a touch material layer above the first pre-pad pattern, patterning the touch material layer to form a second pad pattern and a touch pattern further comprises forming an inorganic material layer on the substrate, patterning the inorganic material layer, and removing the inorganic material layer above and around the first pre-pad pattern to form an inorganic layer, wherein the inorganic layer and the organic protective layer are disposed between the two adjacent pads, and the organic protective layer covers the sidewalls of the pads and the inorganic layer.

### Advantageous Effects

Compared with the prior art, the touch display device and the fabrication method thereof of the present application utilize a touch pattern layer of a touch module together with a source/drain metal layer to form a pad. In a case where a second pad pattern is formed above the pad, sidewalls of the first pad pattern that are defective such as holes generated in the process of forming an anode of an organic light-emitting unit are removed by etching, thereby preventing electrochemical corrosion in the holes and improving reliability of the touch display device.

### BRIEF DESCRIPTION OF DRAWINGS

To detailly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 is a schematic cross-sectional view of a pad of a touch display device in the prior art.

FIG. 2 is a schematic structural diagram of a touch display device according to an embodiment of the application.

FIG. 3 is a schematic plan view of a touch module of the touch display device according to an embodiment of the application.

FIG. 4 is a schematic plan view of the touch display device according to an embodiment of the application.

FIG. 5 is a schematic cross-sectional view of a pad of the touch display device according to an embodiment of the application.

FIG. 6 is a schematic plan view of the pad of the touch display device according to an embodiment of the application.

FIG. 7 is a schematic cross-sectional view of a pad of a touch display device according to another embodiment of the application.

FIG. 8a to 8f are schematic cross-sectional views of a fabrication method of a touch display device according to an embodiment of the application.

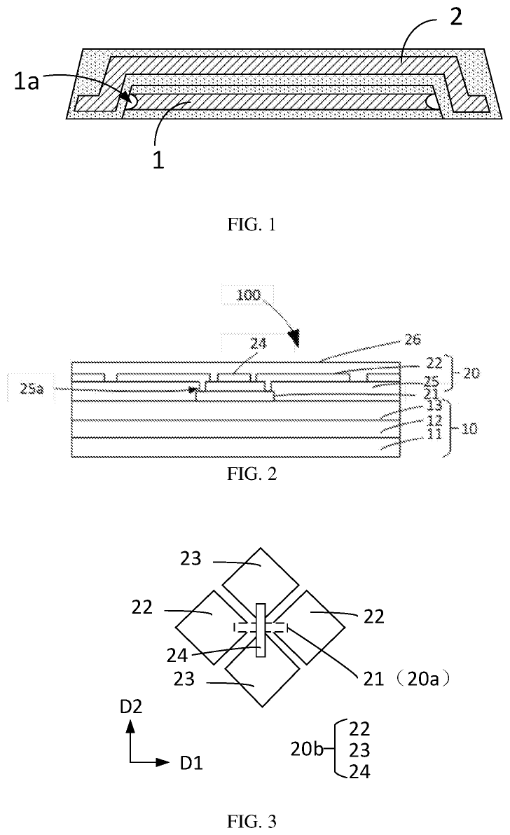

### DETAILED DESCRIPTION

The technical solutions in the embodiments of the present application will be described clearly and completely with reference to the drawings in the embodiments of the present application. Obviously, the described embodiments are only a part of the embodiments of the present application, but not all the embodiments. Based on the embodiments in the present application, all other embodiments obtained by those skilled in the art without making creative work fall within the protection scope of the present application.

Please refer to FIG. 2. The first embodiment of the present application provides a touch display device 100. The touch display device 100 comprises a display module 10 and a touch module 20 that are stacked. The display module 10 comprises an array substrate 11, a plurality of organic light emitting units 12 disposed on the array substrate 11, and a thin film encapsulation layer 13 for encapsulating the plurality of organic light emitting units 12. The organic light emitting units 12 comprise an anode, a cathode, and an organic light emitting layer disposed between the anode and the cathode. Among them, a material of the anode may be a material commonly used in the field, for example, a stack of ITO-Ag-ITO. The touch module 20 is directly formed on the thin film encapsulation layer 13 by using a low temperature process (of a temperature less than or equal to 90° C.) to realize an integration of display and touch.

Please refer to FIG. 3, the touch module 20 comprises a first touch pattern layer 20a and a second touch pattern layer 20b. The first touch pattern layer 20a is disposed between the second touch pattern layer 20b and the display module 10. In one embodiment, the touch module 20 of the touch display device 100 is a single-layered bridge touch structure. Please refer to FIG. 2 and FIG. 3, a specific configuration of the single-layered bridge touch structure will be described below. The touch module 20 comprises a bridge electrode 21 disposed on the thin film encapsulation layer 13, a plurality of first touch patterns 22 disposed along a first direction D1, a plurality of second touch patterns 23 disposed along a second direction D2, and a plurality of connecting electrodes 24 configured to connect two adjacent second touch patterns 23. Herein, the plurality of first touch patterns 22, the plurality of second touch patterns 23, and the plurality of connecting electrodes 24 are located in a same layer and are located above the bridge electrodes 21 and are insulated from the bridge electrodes 21 by an insulating layer 25. That is, the first touch pattern layer 20a comprises the bridge electrode 21. The second touch pattern layer 20b comprises the first touch pattern 22, the second touch pattern 23, and the connection electrode 24. Two adjacent first touch patterns 22 are connected to the same bridge electrode 21 through a through hole 25a in the insulating layer 25. One of the first touch patterns 22 or the second touch patterns 23 is a touch driving electrode, and the other is a touch sensing electrode. In one embodiment, the first direction D1 and the second direction D2 are perpendicular to each other. The first touch pattern 22 and the second touch pattern 23 are formed in a diamond shape. In other embodiments, the first touch pattern 22 and the second touch pattern 23 may also be formed in other shapes such as a long strip. A material of the first touch pattern layer 22 and the second touch pattern 23 can be indium tin oxide (ITO), or gold, silver, copper, lithium, sodium, potassium, magnesium, aluminum, zinc and combinations thereof to form a metal mesh shape. A material of the bridge electrode 21 may be indium tin oxide, or a metal such as a single layer or a stack of copper, silver, molybdenum, aluminum, or molybdenum. In the present embodiment, materials of the first touch pattern layer 20a and the second touch pattern layer 20b are both stacked layers of titanium/aluminum/titanium.

The touch module 20 of the present application is not limited to the above-mentioned structure. In other embodiments of the present application, the touch driving electrodes and the touch sensing electrodes of the touch module 20 are located in different layers. That is, the first touch pattern layer 20a comprises one of the touch drive electrode or the touch sensing electrode, and the second touch pattern layer 20b comprises the other of the touch drive electrode or the touch sensing electrode.

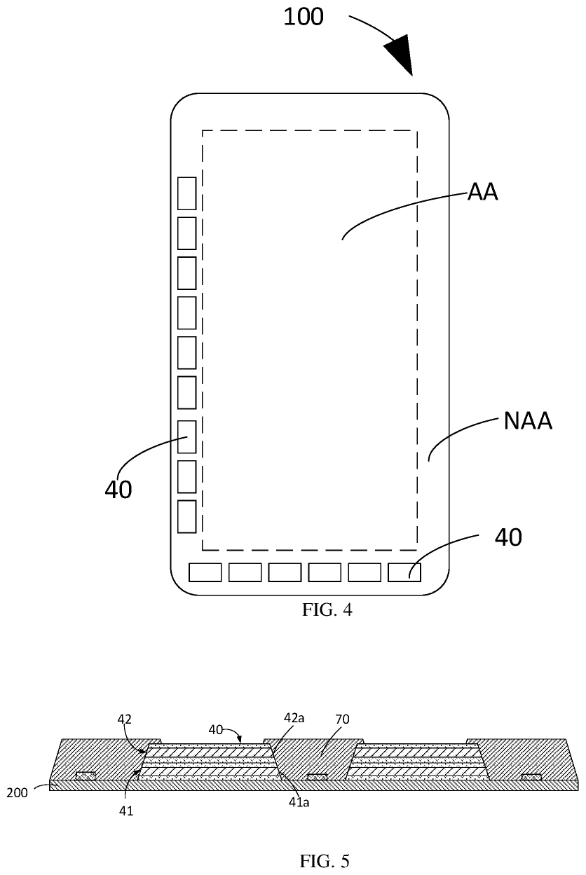

Referring to FIG. 4, the touch display device 100 can be divided into a display area AA and a peripheral area NAA surrounding the display area AA. A plurality of pads 40 are provided in the peripheral area NAA. The pads 40 are configured to connect a display element or a touch element in the touch display device 100 with any signal, for example, electrically connected with a driving chip (IC) through a flexible circuit board (FPC), or directly electrically connected with a chip on film (COF). In addition, the application does not limit the type and function of the pads 40. The pads 40 may be gate bonding pads, source bonding pads, or test bonding pads. They may also be configured as bonding pads of the touch module 20 to electrically connect the touch module 20 and a touch driving chip.

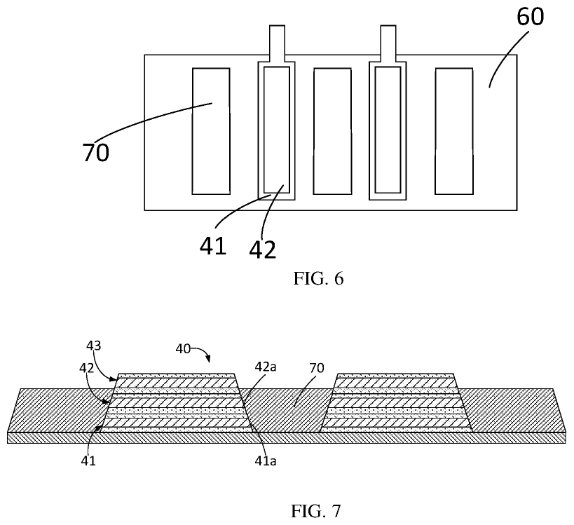

Please refer to FIG. 5 and FIG. 6, the pads 40 comprise a first pad pattern 41 and a second pad pattern 42 located above the first pad pattern 41. The first pad pattern 41 and the second pad pattern 42 are electrically connected to form the pad 40 of the present application. The second pad pattern 42 covers a top surface of the first pad pattern 41 but does not cover sidewalls 41a of the first pad pattern. In other words, the second pad pattern 42 exposes sidewalls 41a of the first pad pattern.

The first pad pattern 41 and the second pad pattern 42 are formed by the same etching step. In one embodiment, in order to simplify the fabrication process, the first pad pattern 41 is over-etched in an etching step of the second pad pattern 42. In other embodiments, the second pad pattern 42 may be etched first, and then sidewalls of the lower metal layer not covered by the second pad pattern 42 may be removed to form the first pad pattern 41.

The present application does not limit a shape of the pads 40. In this embodiment, the pads 40 are formed in a trapezoidal cross section, and the first pad pattern 41 and the second pad pattern 42 are respectively formed in a trapezoidal cross section. Top and bottom surfaces of the first pad pattern 41 and the second pad pattern 42 are rectangular. In other embodiments, the top and bottom surfaces of the first pad pattern 41 and the second pad pattern 42 may also be circular, triangular, polygonal, or other irregular shapes.

The array substrate 11 of the display module 10 comprises a driving circuit of the display module 10, and the driving circuit comprises a plurality of thin film transistors. The first pad pattern 41 and source/drain electrodes of the thin film transistor are formed in the same layer. It can be understood that the first pad pattern 41 can be fabricated by using the same material as the source/drain electrodes of the thin film transistor in the same process. The first pad pattern 41 may be formed using materials used as the source/drain electrodes in the art, for example, using a stack of copper (Cu) and molybdenum (Mo), a stack of copper (Cu) and molybdenum titanium (MoTi) alloy, a stack of copper (Cu) and titanium (Ti), a stack of aluminum (Al), molybdenum (Mo), and copper-niobium (CuNb) alloy. In the present embodiment, the material of the first pad pattern 41 is a stack of titanium/aluminum/titanium.

The second pad pattern 42 and the touch pattern in the touch module 20 are in the same layer. It can be understood that the second pad pattern 42 and the touch pattern in the touch module 20 can be fabricated by using the same material in the same manufacturing process. The touch pattern here refers to electrodes configured to provide touch control in the touch module 20, for example, touch driving electrodes, touch sensing electrodes, or bridge electrodes, which may be included in any one of the first touch pattern layer or the second touch pattern layer. From the perspective of simplifying the fabrication, the second pad pattern 42 and the second touch pattern layer 20b are formed in the same layer, that is, in the same layer with the touch pattern layer far away from the display module 10. In the present embodiment, the second pad pattern 42 and the touch driving electrodes and touch sensing electrodes in the touch module 20 are in the same layer. In other embodiments of the present application, the second pad pattern 42 and the bridge electrode in the touch module 20 may also in the same layer.

In consideration of reducing impedance and simplifying the fabrication, materials of the first pad pattern 41 and the second pad pattern 42 are the same. That is, in the present embodiment, the material of the second pad pattern 42 is a stack of titanium/aluminum/titanium. There is no step formed between the first pad pattern 41 and the second pad pattern 42. Specifically, sidewalls 41a of the first pad pattern 41 and the second pad pattern 42 are connected to sidewalls 42a of the second pad pattern 42 and are located in the same plane. A bottom surface of the second pad pattern 42 has the same shape and size as a top surface of the first pad pattern 41, which completely overlaps thereof.

In other embodiments of the present application, the touch module 20 is not a touch module with a single-layer bridge structure. For example, the touch module 20 comprises a plurality of touch driving electrodes and a plurality of touch sensing electrodes. The touch driving electrodes are disposed in the same layer. The touch sensing electrodes are disposed in the same layer. The touch driving electrodes and the touch sensing electrodes are located in different layers to together form a matrix-type projected capacitor. At this time, the second pad pattern 42 and one of the touch driving electrode or the touch sensing electrode in the touch module 20 are disposed in the same layer.

The touch display device 100 may further comprise an inorganic layer 60 disposed between two adjacent pads 40. The inorganic layer 60 and the insulating layer 25 disposed between the first touch pattern layer 20a and the second touch pattern layer 20b are in the same layer and are formed in the step of forming the insulating layer 25. It can be retained or removed.

In addition, in order to achieve a better bonding, the surface and sidewalls of the pads 40 may be exposed. In some embodiments, the sidewalls of the pads 40 are the sidewalls 41a of the first pad pattern and the sidewalls 42a of the second pad pattern may also be covered by an organic protective layer 70. The organic protective layer 70 may only be provided around the sidewalls 41a of the first pad pattern and the sidewalls 42a of the second pad pattern, or may be filled between two adjacent pads 40. The organic protective layer 70 and an organic protective layer 26 covering the second touch pattern layer 20a may be in the same layer.

In one embodiment, the inorganic layer 60 is covered by the organic protective layer 70.

Referring to FIG. 7, in another embodiment of the present application, the pads 40 further comprise a third bonding pad pattern 43 electrically connected to the second bonding pad pattern 42. The second pad pattern 42 is disposed between the first pad pattern 41 and the third pad pattern 43. The third pad pattern 43 and the first touch pattern 20a are in the same layer, and its material may be the same as the first pad pattern 41 and the second pad pattern 42.

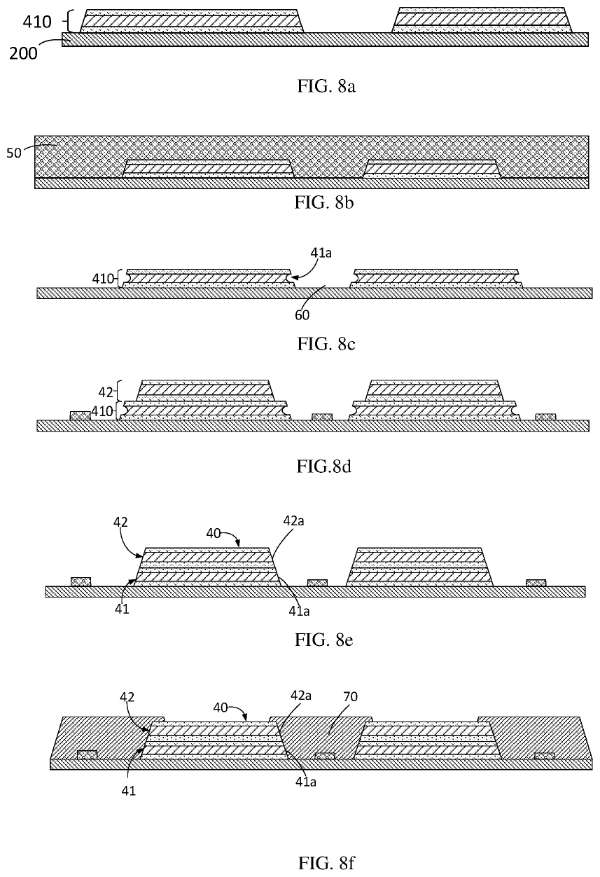

Please refer to FIGS. 8a to 8f, the second embodiment of the present application also provides a fabrication method of the touch display device 100, comprising following steps:

Step S1: providing a substrate 200, forming a source/drain metal layer on the substrate 200, and patterning the source/drain metal layer to form a first pre-pad pattern 410 located in a peripheral area NAA of the touch display device 100 (please refer to FIG. 4) and a source/drain (not shown) of the display area AA of the touch display device 100. The method of patterning the source/drain metal layer may be photolithography.

S2: forming an anode metal layer 50 on the patterned source/drain metal layer, patterning the anode metal layer 50, forming an anode of an organic light emitting diode located in the display area AA and removing the anode metal layer 50 above the first pre-pad pattern 410. Specifically, all the anode metal layer 50 disposed in the peripheral area AA may be removed, or only the anode metal layer 50 above the first pre-pad pattern 410 may be removed, which is not limited in this application. In this step, when the anode metal layer is etched, the first pre-pad pattern 410 is over-etched to form a hole 41a on sidewalls thereof. When the material of the anode metal layer is a stack of ITO-Ag-ITO, defects such as Ag precipitation may also occur.

S3: forming a touch material layer above the first pre-pad pattern 410, patterning the touch material layer, and forming a second pad pattern 42 and a touch pattern (not shown) located in the display area AA of the touch display device 100. The second pad pattern 42 is disposed above the first pre-pad pattern 410 and exposes the sidewalls of the first pre-pad pattern 410. As shown in FIG. 8d, the second pad pattern 42 partially covers the top surface of the first pre-pad pattern 410. As described in the first embodiment, the touch pattern can be a touch driving electrode, a touch sensing electrode, or a bridge electrode. The specific situation has been explained in the first embodiment, and will not be repeated here.

In this step, it may further comprise a step of forming an inorganic material layer on the substrate 200, patterning the inorganic material layer, and removing the inorganic material layer above and around the first pre-pad pattern 410 to form an inorganic layer 60. Herein, the inorganic layer 60 is disposed between two first pre-pad patterns 410. The inorganic material layer is the same layer as the insulating layer 25 disposed between the first touch pattern layer 20a and the second touch pattern layer 20b, and is made in the same step. This step is to remove the insulation barrier between the first pad pattern 41 and the second pad pattern 42. In other methods, the inorganic material layer may be completely removed by patterning.

S4: etching the first pre-pad pattern 410 to form the first pad pattern 41. The first pad pattern 41 and the second pad pattern 42 are electrically connected to form the pad 40 of the present application. In this step, the defective sidewalls 41a of the first pre-pad pattern 410 having holes and the like are removed by etching.

In this embodiment, in order to simplify the fabrication, in step S3, forming a touch material layer on the first pre-pad pattern 410, patterning the touch material layer, and forming the second pad pattern 42 and the touch pattern. In this process, the first pre-pad pattern 410 is simultaneously over-etched to form the first pad pattern 41. In other words, step S4 and step S3 can be the same step.

In other embodiments, an etching can be performed first to form the second pad pattern 42, and then etching the sidewalls of the first pre-pad pattern 410 that are not covered by the second pad pattern 42 to form the first pad pattern 41. The other features of the pad 40 have been described in detail in the first embodiment and will not be repeated again.

In addition, referring to FIG. 8f, after step S4, a step S5 may be further included: forming an organic protective layer 70 covering the sidewalls of the pads 40. The organic protective layer 70 is filled between two adjacent pads 40. The organic protective layer 70 may only be provided around the sidewalls 41a of the first pad pattern and the sidewalls 42a of the second pad pattern, or may be filled between two adjacent pads 40. The organic protective layer 70 can be made in the same layer as an organic protective layer 26 covering the second touch pattern layer 20a and made in the same step. The inorganic layer 60 may also be covered by the organic protective layer 70.

In addition, the specific structure of the touch display device 100, such as the display module 10 and the touch module 20, have been described in the first embodiment, and will not be repeated again.

In another embodiment of the present application, when fabricating the touch display device 100 as shown in FIG. 7, in step S3, two touch material layers are sequentially formed on the first pre-pad pattern 410, and the two touch material layers are patterned to respectively form a second pad pattern 42 and a third pad pattern 43 that are stacked, and a touch pattern (not shown) in the display area AA of the touch display device 100. Step S4 is next performed: etching the first pre-pad pattern 410 to form the first pad pattern 41. The first pad pattern 41, the second pad pattern 42, and the third pad pattern 43 are electrically connected to form the pads 40 of the present application.

Compared with the prior art, the touch display device and the fabrication method thereof of the present application utilize a touch pattern layer of a touch module together with a source/drain metal layer to form a pad. In a case where a second pad pattern is formed above the pad, sidewalls of the first pad pattern that are defective such as holes generated in the process of forming an anode of an organic light-emitting unit are removed by etching, thereby preventing electrochemical corrosion in the holes and improving a reliability of the touch display device.

The descriptions of the above embodiments are only used to help understand the technology of the present application, solutions and their core ideas; those of ordinary skill in the art should understand that they can still modify the technical solutions described in the foregoing embodiments or equivalently replace some of the technical features, and these modifications or replacements do not make the essence of the corresponding technical solutions deviate from the scope of the technical solutions of the embodiments of the present application.

What is claimed is:

1. A touch display device having a stacked display module and a touch module, comprising:
a plurality of pads located in a peripheral area, wherein the pads comprise a first pad pattern and a second pad pattern located above the first pad pattern that is electrically connected to the first pad pattern, the second pad pattern covers a top surface of the first pad pattern and exposes sidewalls of the first pad pattern, the first pad pattern and the second pad pattern are formed in a same etching step, the first pad pattern and source/drain electrodes of the display module are in a same layer, and the second pad pattern and a touch pattern of the touch module are in a same layer.

2. The touch display device of claim 1, wherein the touch module comprises a first touch pattern layer and a second touch pattern layer, the first touch pattern layer is disposed between the second touch pattern layer and the display module, and the second pad pattern and the second touch pattern layer are in the same layer.

3. The touch display device of claim 2, wherein the touch module of the touch display device is a single-layered bridge touch structure, and the second pad pattern and a touch driving electrode and a touch sensing electrode of the touch module are in the same layer.

4. The touch display device of claim 1, wherein the first pad pattern and the second pad pattern are made of a same material.

5. The touch display device of claim 2, wherein the pad further comprises a third pad pattern electrically connected to the second pad pattern, the second pad pattern is located between the first pad pattern and the third pad pattern, and the third pad pattern and the first pad pattern are in the same layer.

6. The touch display device of claim 1, wherein sidewalls of the pads are covered by an organic protective layer.

7. The touch display device of claim 1, further comprising an inorganic layer disposed between two adjacent pads.

8. The touch display device of claim 1, wherein the touch display device further comprises an inorganic layer and an organic protective layer disposed between two adjacent pads, and the organic protective layer covers sidewalls of the pads and the inorganic layer.

9. A fabrication method of a touch display device, wherein the touch display device comprises a stacked display module and a touch module, and further comprises a plurality of pads located in a peripheral area, and the fabrication method comprises following steps:
providing a substrate, forming a source/drain metal layer on the substrate, and patterning the source/drain metal layer to form a first pre-pad pattern and a source/drain;
forming an anode metal layer on the patterned source/drain metal layer, patterning the anode metal layer, and forming an anode and removing the anode metal layer above the first pre-pad pattern;
forming a touch material layer above the first pre-pad pattern, patterning the touch material layer to form a second pad pattern and a touch pattern, wherein the second pad pattern is located on the first pre-pad pattern and exposes sidewalls of the first pre-pad pattern; and
etching the first pre-pad pattern to form a first pad pattern, wherein the first pad pattern and the second pad pattern are electrically connected to form the pads.

10. The fabrication method of the touch display device according to claim 9, wherein in the step of forming the touch material layer above the first pre-pad pattern, patterning the touch material layer to form the second pad pattern and the touch pattern, over-etching is simultaneously performed to the first pre-pad pattern to form the first pad pattern.

11. The fabrication method of the touch display device according to claim 9, wherein the touch module comprises a first touch pattern layer and a second touch pattern layer, the first touch pattern layer is disposed between the second touch pattern layer and the display module, and the second pad pattern and the second touch pattern layer are in a same layer.

12. The fabrication method of the touch display device according to claim 11, wherein the touch module of the touch display device is a single-layer bridge touch structure, and the second pad pattern and a touch driving electrode and a touch sensing electrode of the touch module are in the same layer.

13. The fabrication method of the touch display device according to claim 9, wherein the first pad pattern and the second pad pattern are made of a same material.

14. The fabrication method of the touch display device according to claim 9, wherein in the step of forming the touch material layer above the first pre-pad pattern, patterning the touch material layer to form the second pad pattern and the touch pattern, two layers of touch material are sequentially formed above the first pre-pad pattern, and the two layers of touch material are patterned to respectively form stacked second and third pad patterns.

15. The fabrication method of the touch display device of claim 9, further comprising forming an organic protective layer covering sidewalls of the pads.

16. The fabrication method of the touch display device according to claim 9, wherein in the step of forming the touch material layer above the first pre-pad pattern, patterning the touch material layer to form the second pad pattern and the touch pattern, further comprises forming an inorganic material layer on the substrate, patterning the inorganic material layer, and removing the inorganic material layer above and around the first pre-pad pattern to form an inorganic layer.

17. The fabrication method of the touch display device according to claim 15, wherein in the step of forming the touch material layer above the first pre-pad pattern, patterning the touch material layer to form the second pad pattern and the touch pattern, further comprises forming an inorganic material layer on the substrate, patterning the inorganic material layer, and removing the inorganic material layer above and around the first pre-pad pattern to form an inorganic layer, wherein the inorganic layer and the organic protective layer are disposed between two adjacent pads, and the organic protective layer covers the sidewalls of the pads and the inorganic layer.
